(19) United States
(12) Patent Application Publication
(10) Pub. No.: US 2024/0307821 A1
(43) Pub. Date: Sep. 19, 2024

(54) SUBSTRATE PROCESSING SYSTEM AND SUBSTRATE PROCESSING METHOD

(71) Applicant: Tokyo Electron Limited, Tokyo (JP)

(72) Inventors: Yosuke HACHIYA, Kumamoto (JP); Mitsunori NAKAMORI, Kumamoto (JP); Koji KAGAWA, Kumamoto (JP)

(21) Appl. No.: 18/576,898

(22) PCT Filed: Jun. 22, 2022
(86) PCT No.: PCT/JP2022/024960

§ 371 Date: Jan. 5, 2024

(30) Foreign Application Priority Data
Jul. 6, 2021 (JP) 2021-111943

(51) Int. Cl. B01D 53/90; B08B 3/04; F26B 5/00

(52) U.S. Cl. CPC B01D 53/90; B08B 3/048; F26B 5/005

(57) ABSTRACT

A substrate processing system includes a batch processor, a single-substrate processor, and a transferrer. The batch processor collectively processes a plurality of substrates by immersing the plurality of substrates in ozonated water stored in a processing tank. The single-substrate processor processes the plurality of substrates one by one with a chemical liquid. The transferrer transfers the plurality of substrates in a wet state from the batch processor to the single-substrate processor.

### TECHNICAL FIELD

The present disclosure relates to a substrate processing system and a substrate processing method.

### BACKGROUND

A substrate processing apparatus disclosed in Patent Document 1 includes an adjustment liquid supplier, a dissoluter, a processing chamber, and a liquid feeder. The adjustment liquid supplier supplies an adjustment liquid having a predetermined hydrogen ion concentration. The dissoluter generates ozonated water by dissolving an ozone gas in the adjustment liquid. The processing chamber cleans a substrate with the ozonated water. The liquid feeder feeds the ozonated water from the dissoluter to at least one processing chamber through a liquid feed line.

### PRIOR ART DOCUMENT

### [Patent Document]

Patent Document 1: International publication No. 2020/100661

### SUMMARY

One aspect of the present disclosure provides a technique that improves the processing efficiency of a substrate by ozonated water and improves the cleanliness of the substrate processed with the ozonated water.

According to one aspect of the present disclosure, there is provided a substrate processing system including a batch processor, a single-substrate processor, and a transferrer. The batch processor collectively processes a plurality of substrates by immersing the plurality of substrates in ozonated water stored in a processing tank. The single-substrate processor processes the substrates one by one with a chemical liquid. The transferrer transfers the substrates in a wet state from the batch processor to the single-substrate processor.

According to one aspect of the present disclosure, the processing efficiency of a substrate by ozonated water is improved and the cleanliness of the substrate processed with the ozonated water is improved.

### BRIEF DESCRIPTION OF DRAWINGS

FIG. 1 is a plan view illustrating a substrate processing system according to an embodiment.

FIG. 2 is a flowchart illustrating a substrate processing method according to an embodiment.

FIG. 3 is a diagram illustrating an example of a supplier that supplies ozonated water to a processing tank.

FIG. 4 is a diagram illustrating another example of the supplier that supplies the ozonated water to the processing tank.

FIG. 5 is a cross-sectional view illustrating an example of a batch-type liquid processing device.

FIG. 6 is a cross-sectional view taken along line VI-VI in FIG. 5.

FIG. 7 is a plan view illustrating an example of arrangement of an exhaust port of a gas discharge nozzle and a substrate.

FIG. 8 is a diagram illustrating an example of components of a controller in functional blocks.

FIG. 9 is a flowchart illustrating an example of batch processing.

FIG. 10 is a cross-sectional view illustrating an example of S209 in FIG. 9.

FIG. 11 is a cross-sectional view illustrating an example of S210 in FIG. 9.

FIG. 12 is a flowchart illustrating another example of batch processing.

### DETAILED DESCRIPTION

Hereinafter, embodiments of the present disclosure will be described with reference to the accompanying drawings. In each drawing, the same or corresponding configurations are denoted by the same reference numerals, and descriptions thereof may be omitted.

Generally, aqueous solution containing sulfuric acid and hydrogen peroxide (SPM) is used to remove residues after photoresist is removed by ashing. Since SPM contains sulfuric acid, the cost of draining SPM is high. Therefore, using ozonated water instead of SPM is under consideration. As disclosed in Patent Document 1, when processing one substrate at a time with ozonated water, throughput is deteriorated compared to when processing one substrate at a time with SPM.

As will be described in detail later, the technology of the present disclosure improves throughput by immersing a plurality of substrates in ozonated water and collectively processing the substrates. Collectively processing a plurality of substrates is also called batch processing, and processing a single substrate at a time is also called single-substrate processing. Although the batch processing improves throughput compared to the single-substrate processing, the batch processing tends to leave contaminants on a substrate.

Therefore, in the technology of the present disclosure, substrates are transferred in a wet state from a batch processor to a single-substrate processor. This is because, if the substrates are dry, contaminants will firmly adhere to the substrates. By transferring the substrates in a wet state, contaminants may be prevented from firmly adhering to the substrates. Further, the technology of the present disclosure processes one substrate at a time with a chemical liquid in the single-substrate processor to remove contaminants remaining on the substrate. By processing one substrate at a time with the chemical liquid, secondary contaminants may be suppressed. Therefore, the cleanliness of the substrates batch-processed with the ozonated water may be improved.

The ozonated water only needs to change contaminants on the substrates to an extent that the contaminants is easily dissolved in the chemical liquid. The chemical liquid uses, for example, alkaline solution such as SC1 solution (aqueous solution containing ammonium hydroxide and hydrogen peroxide) without being particularly limited. For example, the ozonated water oxidizes resist residues to lower molecular weight of the resist residues. On the other hand, the alkaline solution dissolves and removes the low-molecular-weight resist residues. The technology of the present disclosure may also be applied to processes other than removing the resist residues.

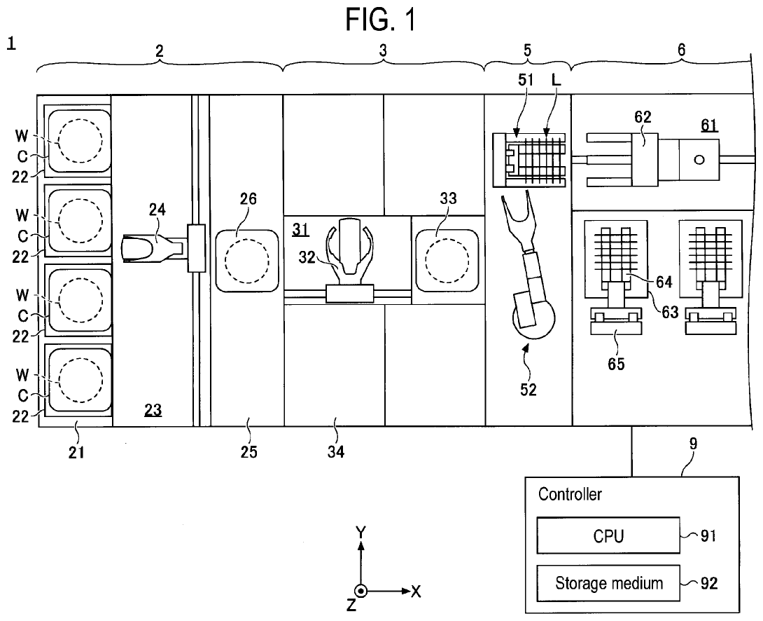

Next, a substrate processing system according to an embodiment will be described with reference to FIG. 1. A substrate processing system 1 includes a loading/unloading part 2, a single-substrate processor 3, an interface 5, a batch processor 6, and a controller 9. The loading/unloading part 2 includes a stage 21 on which a cassette C is placed. The cassette C accommodates a plurality of (e.g., 25) substrates W and is loaded into and unloaded from the loading/unloading part 2. Inside the cassette C, the substrates W are held horizontally. The single-substrate processor 3 processes the substrates W one by one. The interface 5 delivers the substrates W between the single-substrate processor 3 and the batch processor 6. The batch processor 6 collectively processes the plurality of (e.g., 50 or 100) substrates W.

The loading/unloading part 2, the single-substrate processor 3, the interface 5, and the batch processor 6 are arranged in this order from the negative side of the X-axis direction to the positive side of the X-axis direction. The loading/unloading part 2 includes the stage 21. The stage 21 includes a plurality of placement plates 22. The cassette C is placed on each placement plate 22. The number of placement plates 22 is not particularly limited. Similarly, the number of cassettes C is not particularly limited.

The loading/unloading part 2 includes a first transfer area 23. The first transfer area 23 is adjacent to the stage 21 and is arranged on the positive side of the X-axis direction of the stage 21. A first transfer device 24 is provided in the first transfer area 23. The first transfer device 24 includes a first transfer arm which moves in a horizontal direction (X-axis direction and Y-axis direction) and a vertical direction and rotates around a vertical axis. The first transfer arm transfers the substrates W between the cassette C and a deliverer 25 which will be described later. The number of first transfer arms may be one or plural. In the latter case, the first transfer device 24 collectively transfers a plurality of (e.g., five) substrates W.

The loading/unloading part 2 includes the deliverer 25. The deliverer 25 is adjacent to the first transfer area 23 and is arranged on the positive side of the X-axis direction of the first transfer area 23. The deliverer 25 includes a first transition device 26 that temporarily stores the substrates W. The number of first transition devices 26 may be plural. The plurality of first transition devices 26 may be stacked in the vertical direction.

The single-substrate processor 3 has a second transfer area 31. The second transfer area 31 is adjacent to the deliverer 25 and is arranged on the positive side of the X-axis direction of the deliverer 25. A second transfer device 32 is provided in the second transfer area 31. The second transfer device 32 includes a second transfer arm which moves in the horizontal direction (X-axis direction and Y-axis direction) and the vertical direction and rotates around the vertical axis. The second transfer arm transfers the substrates between devices adjacent to the second transfer area 31. The number of second transfer arms may be one or plural. In the latter case, the second transfer device 32 collectively transfers a plurality of (e.g., five) substrates W.

The single-substrate processor 3 includes, for example, a second transition device 33 and a liquid processing device 34, adjacent to the second transfer area 31. The second transition device 33 is adjacent to the second transfer area 31 and is arranged on the positive side of the X-axis direction of the second transfer area 31. The second transition device 33 temporarily stores the substrates W. The liquid processing device 34 is a single-substrate processing type and processes one substrate W at a time with a chemical liquid.

The interface 5 includes, for example, a lot former 51 and a transferrer 52. The lot former 51 arranges the plurality of substrates W at a desired pitch to form a lot L. One lot L is composed of the plurality of substrates W. The transferrer 52 transfers the substrates W from the single-substrate processor 3 to the lot former 51 and transfers the substrates W from the batch processor 6 to the single-substrate processor 3.

The batch processor 6 has a third transfer area 61. The third transfer area 61 is adjacent to the interface 5 and is arranged on the positive side of the X-axis direction of the interface 5. A third transfer device 62 is provided in the third transfer area 61. The third transfer device 62 includes a third transfer arm which moves in the horizontal direction (X-axis direction and Y-axis direction) and the vertical direction and rotates around the vertical axis. The third transfer arm transfers the substrates W between devices adjacent to the third transfer area 61. The third transfer arm collectively transfers the lots L.

The third transfer area 61 is rectangular in a plan view, and a longitudinal direction thereof is the X-axis direction. The lot former 51 is arranged adjacent to the short side of the third transfer area 61. A processing tank 63 is arranged adjacent to the long side of the third transfer area 61. A transferrer 52 is arranged adjacent to both the lot former 51 and the processing tank 63. The transferrer 52 may access both the lot former 51 and the processing tank 63.

The arrangement direction of the substrates W is different between the lot former 51 and the processing tank 63. Therefore, the third transfer device 62 rotates around the vertical axis while holding the plurality of substrates W and changes the arrangement direction of the substrates W between the X-axis direction and the Y-axis direction. If it is not necessary to change the arrangement direction of the substrates W, the third transfer device 62 does not need to rotate around the vertical axis.

The batch processor 6 includes the processing tank 63 that stores ozonated water in which the lot L is immersed, and a substrate holder 64 that receives the lot L from the third transfer device 62 and holds the lot L. The substrate holder 64 arranges the plurality of substrates W side by side in the Y-axis direction and holds each substrate W vertically. The batch processor 6 includes a driving device 65 that raises and lowers the substrate holder 64.

The controller 9 is, for example, a computer, and includes a central processing unit (CPU) 91 and a storage medium 92 such as a memory. The storage medium 92 stores a program that controls a variety of processes executed in the substrate processing system 1. The controller 9 controls the operation of the substrate processing system 1 by causing the CPU 91 to execute the program stored in the storage medium 92.

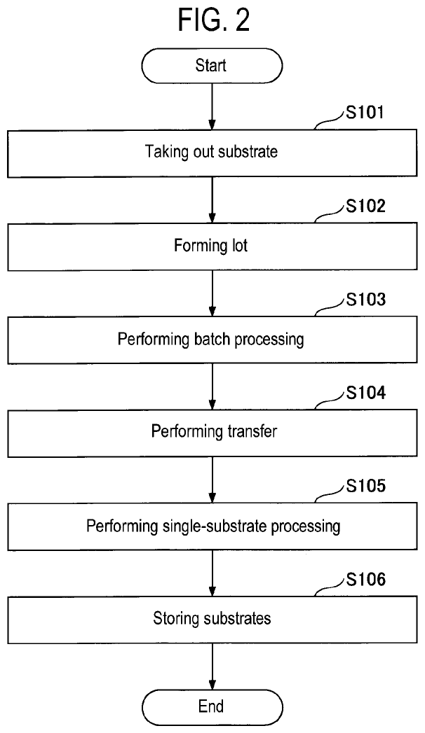

Next, an operation of the substrate processing system 1, i.e., a substrate processing method, will be described with reference to FIG. 2. Processing shown in FIG. 2 is implemented under control of the controller 9. First, the cassette C accommodating the plurality of substrates W is loaded into the loading/unloading part 2 and is placed on the placement plate 22.

Subsequently, the first transfer device 24 takes out the substrate W in the cassette C (step S101) and transfers the substrate W to the first transition device 26. Subsequently, the second transfer device 32 receives the substrate W from the first transition device 26 and transfers the substrate W to the second transition device 33. Thereafter, the transferrer 52 receives the substrate W from the second transition device 33 and transfers the substrate W to the lot former 51.

Thereafter, the lot former 51 forms the lot L by arranging the plurality of substrates W at a desired pitch in the X-axis direction (step S102). One lot L is composed of the substrates W accommodated in, for example, N (where N is a natural number of 2 or more) cassettes C.

Subsequently, the third transfer device 62 receives the lot L from the lot former 51 and delivers the lot L to the substrate holder 64. The third transfer device 62 rotates around the vertical axis, while the lot L is delivered, and changes the arrangement direction of the plurality of substrates W from the X-axis direction to the Y-axis direction.

Thereafter, the driving device 65 lowers the substrate holder 64 to immerse the lot L held by the substrate holder 64 in the ozonated water stored in the processing tank 63 and collectively batch-processes the plurality of substrates W (step S103). The plurality of substrates W is immersed in the ozonated water and then immersed in a rinsing liquid. The rinsing liquid is, for example, deionized water (DIW). Subsequently, the driving device 65 raises the substrate holder 64 to pull up the lot L held by the substrate holder 64 from the rinsing liquid stored in the processing tank 63.

The processing tank 63 that stores the rinsing liquid and the processing tank 63 that stores the ozonated water may be separately provided. In this case, in order to transfer the plurality of substrates W between the two processing tanks 63, the driving device 65 may not only raise the substrate holder 64 in the vertical direction, but also move the substrate holder 64 in the horizontal direction (e.g., in the X-axis direction). Here, the substrate holder 64 and the driving device 65 may be provided for each processing tank 63. In this case, the driving device 65 does not need to move the substrate holder 64 in the horizontal direction.

Subsequently, the transferrer 52 receives the substrates W from the substrate holder 64 and transfers the substrates W in a wet state from the batch processor 6 to the single-substrate processor 3 (step S104). In this case, although the transferrer 52 transfers one substrate W at a time, the transferrer 52 may transfer a plurality of substrates W at a time. The substrates W may be transferred to the liquid processing device 34 without passing through the second transition device 33 or may be transferred to the liquid processing device 34 via the second transition device 33. In the latter case, the second transfer device 32 may transfer the substrates W from the second transition device 33 to the liquid processing device 34.

Subsequently, the liquid processing device 34 processes the substrates W one by one with a chemical liquid (step S105). The chemical liquid uses, for example, an alkaline solution such as SC1 without being particularly limited. The liquid processing device 34 supplies the chemical liquid to the substrates W, for example, while rotating the substrates W. The chemical liquid is shaken off from the substrates W by virtue of a centrifugal force in a state of containing contaminants on the substrates W.

The liquid processing device 34 supplies, for example, the chemical liquid, a rinsing liquid, and a drying liquid to the substrates W in this order. As the drying liquid, for example, an organic solvent such as isopropyl alcohol (IPA) may be used. The liquid processing device 34 rotates the substrates W to shake off the drying liquid adhering to the substrates W and dry the substrates W.

The single-substrate processor 3 may include a supercritical drying device. In this case, the substrates W are transferred to the supercritical drying device in a state in which the drying liquid is sufficiently applied. The supercritical drying device dries the substrates W using supercritical fluid.

Subsequently, the second transfer device 32 receives the substrates W from the liquid processing device 34 and transfers the substrates W to the first transition device 26. Subsequently, the first transfer device 24 receives the substrates W from the first transition device 26 and stores the substrates W in the cassette C (step S105). The cassette C is unloaded from the loading/unloading part 2 with the plurality of substrates W accommodated therein.

As described above, the substrate processing system 1 collectively immerses the plurality of substrates W in the ozonated water stored in the processing tank 63 in the batch processor 6, transfers the substrates W from the batch processor 6 to the single-substrate processor 3 in a wet state, and processes the substrates W one by one with a chemical liquid in the single-substrate processor. Since the plurality of substrates W is collectively immersed in the ozonated water, throughput is improved. Thereafter, since the substrates W are transferred in a wet state from the batch processor 6 to the single-substrate processor 3, contaminants are suppressed from firmly adhering to the substrates W. Further, since the single-substrate processor 3 processes the substrates W one by one with a chemical liquid, the cleanliness of the substrates W batch-processed with the ozonated water is improved.

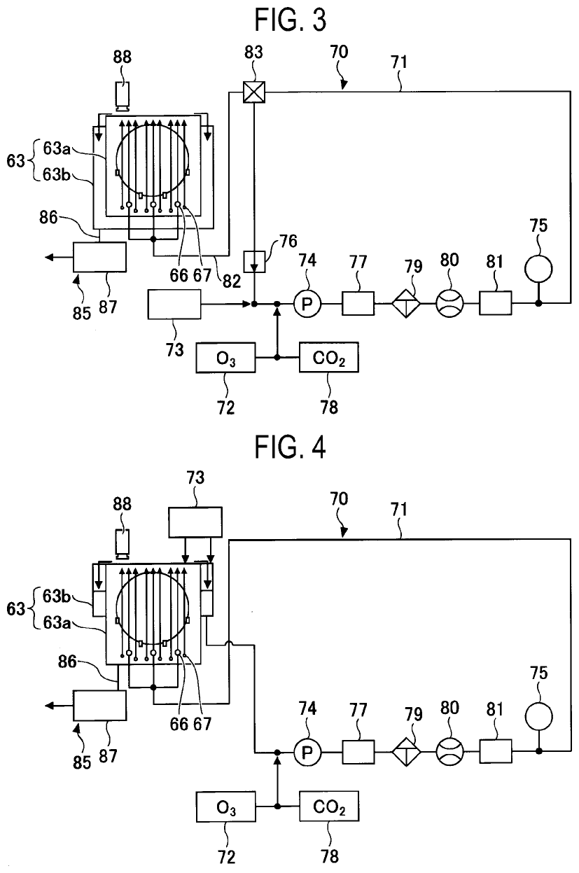

Subsequently, an example of a supplier 70 that supplies the ozonated water to the processing tank 63 will be described with reference to FIG. 3. The supplier 70 includes a circulation path 71 and an ozone gas supplier 72. The circulation path 71 circulates the ozonated water. The capacity of the circulation path 71 is larger than the amount of ozonated water used in one round of batch processing. The ozone gas supplier 72 supplies an ozone gas to the circulation path 71. The ozone gas is dissolved in water to generate the ozonated water. The water is DIW or the like and is supplied from a liquid source 73 to the circulation path 71. While the ozonated water circulates through the circulation path 71, the ozone gas is dissolved in the ozonated water, and an ozone concentration of the ozonated water gradually increases.

The liquid source 73 may supply an acidic aqueous solution to the circulation path 71 instead of water. The acidic aqueous solution contains organic acid or inorganic acid. As the organic acid, for example, citric acid, acetic acid, carbonic acid, or the like may be used. As the inorganic acid, hydrochloric acid, nitric acid, or the like may be used. The acidic aqueous solution is effective in removing metal ions contained in resist residues.

The supplier 70 includes a pressurizing device 74, a pressure gauge 75, and a pressure control valve 76. The pressurizing device 74 is, for example, a pump, and increases the limit amount (solubility) of ozone gas dissolved in water by pressurizing the ozonated water in the circulation path 71. The pressure gauge 75 measures a pressure of the ozonated water. The pressure control valve 76 controls the pressure of the ozonated water so that the measured value of the pressure gauge 75 becomes a set value.

The supplier 70 includes a cooling device 77. The cooling device 77 cools the ozonated water in the circulation path 71 to increase the solubility of ozone gas. The cooling device 77 includes, for example, a Peltier element. A thermometer (not shown) may be provided in the circulation path 71. The cooling device 77 cools the ozone gas so that a temperature of the thermometer reaches a set temperature.

The supplier 70 includes a carbon dioxide gas supplier 78. The carbon dioxide gas supplier 78 supplies a carbon dioxide gas (CO2 gas) to the circulation path 71. When the carbon dioxide gas is dissolved in the ozonated water, a pH value of the ozonated water decreases, and the solubility of the ozone gas increases. An organic acid or an inorganic acid may be supplied instead of the carbon dioxide gas.

The supplier 70 includes a filter 79, a flow meter 80, and an ozone concentration meter 81. The filter 79 collects particles contained in the ozonated water in the circulation path 71. The flow meter 80 measures a flow rate of the ozonated water flowing through the circulation path 71. The ozone concentration meter 81 measures an ozone concentration of the ozonated water flowing through the circulation path 71.

The supplier 70 includes a branch path 82 and a direction switching valve 83. The branch path 82 is branched at the circulation path 71 and supplies the ozonated water flowing through the circulation path 71 to the processing tank 63. The direction switching valve 83 switches a direction in which the ozonated water flows to a direction in which the ozonated water is circulated in the circulation path 71 and a direction in which the ozonated water is supplied to the processing tank 63.

The processing tank 63 includes, for example, an inner tank 63a and an outer tank 63b. The inner tank 63a stores the ozonated water. The plurality of substrates W is immersed in the ozonated water stored in the inner tank 63a. The outer tank 63b collects the ozonated water that overflows from the inner tank 63a. A discharger 85 is connected to the processing tank 63.

The discharger 85 discharges the ozonated water that has been used. The discharger 85 includes a discharge path 86 and a drainage processor 87. The discharge path 86 is connected to the processing tank 63. The drainage processor 87 includes an ozone filter that decomposes ozone into oxygen. The ozone filters have catalysts or activated carbon. The drainage processor 87 includes a mesh filter that collects resist residues.

A capturing device 88 captures an image of the ozonated water stored in the processing tank 63 (e.g., the inner tank 63a). The higher the ozone concentration of the ozonated water, the deeper the blue color of the ozonated water becomes. The ozone concentration of the ozonated water may be detected by processing the image captured by the capturing device 88 and acquiring color information about the ozonated water.

A place where the substrate W is immersed in the ozonated water is not the circulation path 71 but the processing tank 63. Since the processing tank 63 has a lower pressure of the ozonated water and a lower solubility of the ozone gas than the circulation path 71, there is a possibility that the ozone concentration of the ozonated water is low. When the capturing device 88 is used instead of the ozone concentration meter 81, the ozone concentration of the ozonated water may be detected in the place where the substrate W is immersed in the ozonated water.

The capturing device 88 is installed, for example, above the processing tank 63 so as not to get wet, and captures an image of a liquid level of the ozonated water.

Subsequently, another example of the supplier 70 that supplies the ozonated water to the processing tank 63 will be described with reference to FIG. 4. Differences between FIG. 3 and FIG. 4 will be mainly described below. The circulation path 71 shown in FIG. 3 is closed in an endless ring shape, whereas the circulation path 71 shown in FIG. 4 is open. The processing tank 63 includes the inner tank 63a and the outer tank 63b, and the circulation path 71 connects the outer tank 63b and the inner tank 63a as shown in FIG. 4. One end of the circulation path 71 is connected to the outer tank 63b, and the other end of the circulation path 71 is connected to the inner tank 63a. The circulation path 71 returns the ozonated water extracted from the outer tank 63b to the inner tank 63a. The liquid source 73 may be connected to at least one of the inner tank 63a and the outer tank 63b as shown in FIG. 4 instead of being connected to the circulation path 71 as shown in FIG. 3.

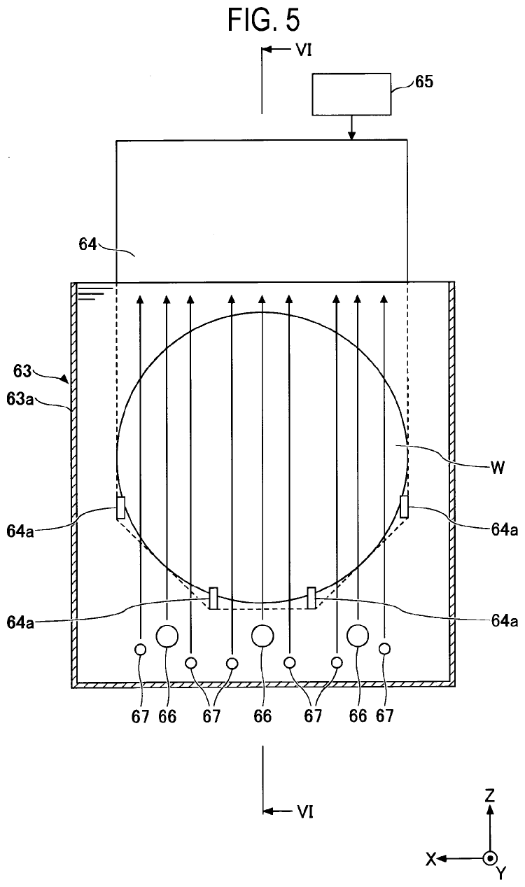

Subsequently, an example of a batch-type liquid processing device will be described with reference to FIGS. 5 to 7. The batch-type liquid processing device includes a processing tank 63, a substrate holder 64, a driving device 65, a liquid discharge nozzle 66, and a gas discharge nozzle 67.

The processing tank 63 stores the ozonated water in which the plurality of substrates W is collectively immersed at once. The processing tank 63 may store a rinsing liquid. The processing tank 63 may be provided with an ultrasonic generator (not shown). The ultrasonic generator applies ultrasonic vibration to the ozonated water, thereby improving the cleaning efficiency of the substrate W with the ozonated water.

The substrate holder 64 arranges the plurality of substrates W side by side in the Y-axis direction and holds each substrate W vertically. The substrate holder 64 includes a plurality of (e.g., four) holding arms 64a. Each holding arm 64a is provided in the Y-axis direction and has a plurality of grooves spaced apart from each other in the Y-axis direction. Each substrate W is held by the grooves of the holding arm 64a.

The driving device 65 raises and lowers the substrate holder 64. The substrate holder 64 is raised and lowered between a position inside the processing tank 63 and a position above the processing tank 63. As described above, the driving device 65 may move the substrate holder 64 in the horizontal direction.

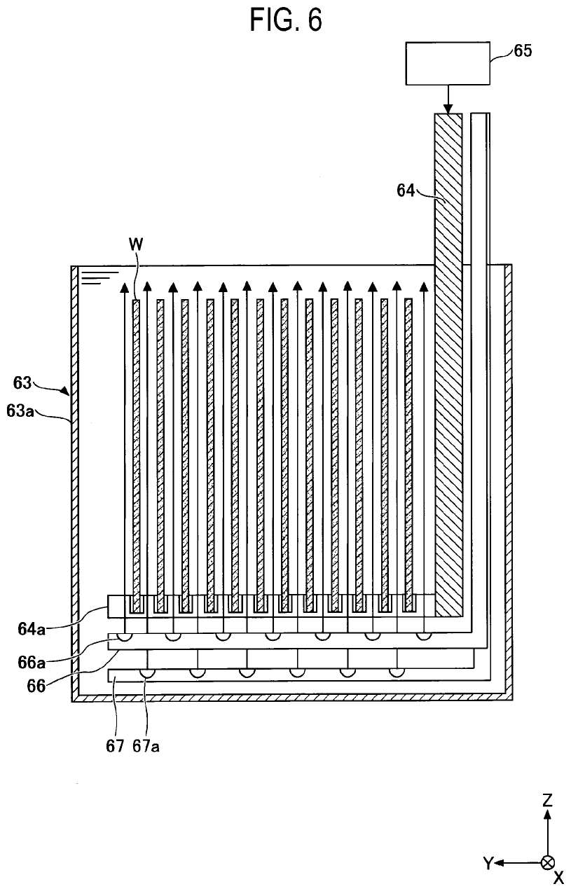

The liquid discharge nozzle 66 is provided horizontally inside the processing tank 63 and discharges a processing liquid into the processing tank 63. The processing liquid to be discharged is the ozonated water or the rinsing liquid supplied from the supplier 70. The liquid discharge nozzle 66 is provided, for example, in the Y-axis direction. A plurality of liquid discharge nozzles may be provided at intervals in the X-axis direction. Each liquid discharge nozzle 66 has a plurality of exhaust ports 66a at intervals in the Y-axis direction. Each discharge port 66a is provided below the substrate W immersed in the processing liquid. Although each discharge port 66a discharges the processing liquid directly upward in FIGS. 5 and 6, the discharge port 66a may discharge the processing liquid obliquely upward.

The gas discharge nozzle 67 is provided horizontally inside the processing tank 63 and discharges gas into the processing tank 63. The gas discharge nozzle 67 is provided, for example, in the Y-axis direction. A plurality of gas discharge nozzles 67 may be provided at intervals in the X-axis direction. Each gas discharge nozzle 67 has a plurality of discharge ports 67a at intervals in the Y-axis direction. Each discharge port 67a is provided below the substrate W immersed in the processing liquid. Although each discharge port 67a discharges the processing liquid directly upward in FIGS. 5 and 6, the discharge port 67a may discharge the processing liquid obliquely upward. The discharge port 67a of the gas discharge nozzle 67 is provided below the discharge port 66a of the liquid discharge nozzle 66.

The processing tank 63 stores the ozonated water, and the gas discharge nozzle 67 discharges the gas while the substrate W is immersed in the ozonated water. The gas increases the flow rate of the ozonated water and causes the ozonated water to reach resist residues before the ozonated water is deactivated. Thus, the removal efficiency of the resist residues is improved.

When the ozonated water is stored in the processing tank 63, the gas discharge nozzle 67 discharges an oxygen gas or a noble gas, for example. Unlike a nitrogen gas, since the oxygen gas or the noble gas does not react with ozone, the ozonated water may be suppressed from being deactivated.

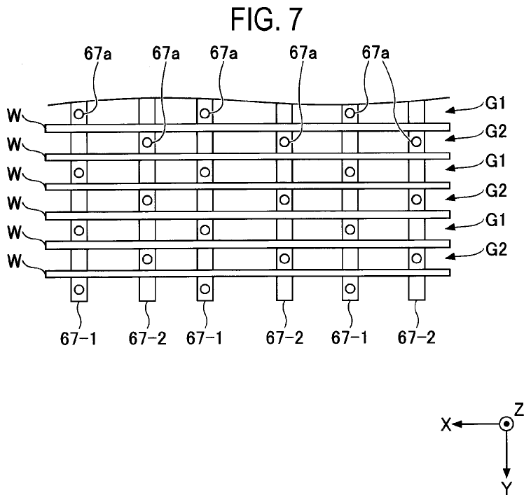

As shown in FIG. 7, when viewed from above, each of gas discharge nozzles 67-1 and 67-2 includes an discharge port 67a in a first gap G1 or a second gap G2 of two substrates W adjacent in the Y-axis direction. The discharge port 67a discharges gas directly above. Since the substrates W do not hinder the discharged gas from rising, the flow rate of the ozonated water is easily increased, and the resist residues are easily removed.

When viewed from above, the first gap G1 and the second gap G2 are arranged alternately in the Y-axis direction, and the gas discharge nozzle 67-1 having the discharge port 67a only in the first gap G1 and the gas discharge nozzle 67-2 having the discharge ports 67a only in the second gap G2 are provided alternately in the X-axis direction. Gas may be discharged widely and uniformly to both the first gap G1 and the second gap G2.

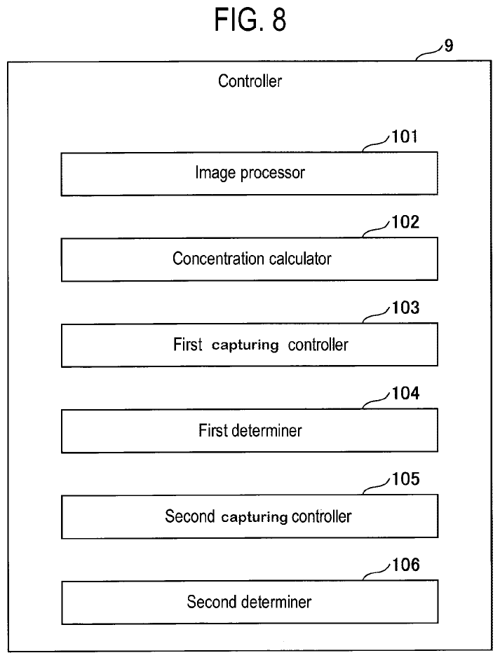

As shown in FIG. 8, the controller 9 includes, for example, an image processor 101, a concentration calculator 102, a first capturing controller 103, a first determiner 104, a second capturing controller 105, and a second determiner 106.

The image processor 101 processes the image captured by the capturing device 88 and obtains color information about the ozonated water. By using the capturing device 88, it is possible to detect the ozone concentration of the ozonated water that actually contacts the substrate W. The concentration calculator 102 calculates the ozone concentration of the ozonated water based on the color information about the ozonated water obtained by the image processor 101. The color information itself may also be used as an index representing the ozone concentration without calculating the ozone concentration.

The first capturing controller 103 controls the capturing device 88 to capture an image of the ozonated water before the plurality of substrates W is immersed in the ozonated water after the ozonated water is stored in the processing tank 63. The first determiner 104 determines whether to immerse the substrates W in the ozonated water based on the color information about the ozonated water acquired by the image processor 101. The substrates W are immersed in the ozonated water in which the color information or the ozone concentration calculated from the color information is within a set range. When the color information or the ozone concentration is outside the set range, the discharger 85 discharges the ozonated water from the processing tank 63, and the supplier 70 supplies new ozonated water to the processing tank 63. Deterioration in quality of the substrate W due to abnormal ozone concentration may be suppressed.

The second capturing controller 105 controls the capturing device 88 to capture an image of the ozonated water while the plurality of substrates W is immersed in the ozonated water stored in the processing tank 63. The second determiner 106 determines whether processing on the plurality of substrates W has been performed normally, based on the color information about the ozonated water captured under control of the second capturing controller 105. When the color information or the ozone concentration calculated from the color information is within a set range, it is determined that processing has been performed normally and, otherwise, it is determined that processing has been performed abnormally. The processing quality of the substrate W may be easily determined.

Further, each functional block illustrated in FIG. 8 is conceptual and does not necessarily need to be physically configured as illustrated. All or a portion of each functional block illustrated in FIG. 8 may be distributed or integrated functionally or physically in arbitrary units. All or any portion of each processing function performed by each functional block may be implemented by a program executed by a CPU or may be implemented as hardware using wired logic.

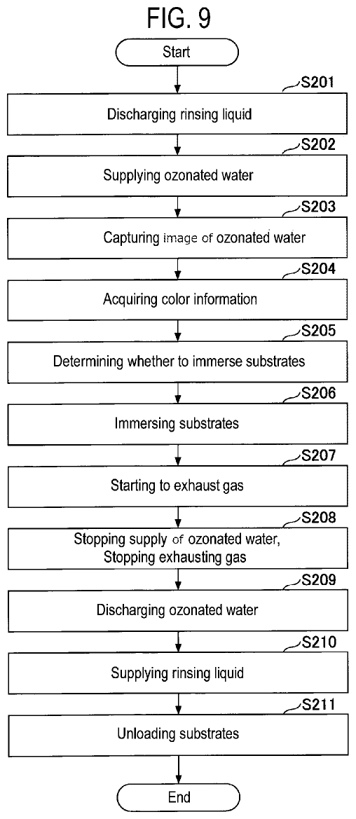

Subsequently, an example of batch processing will be described with reference to FIGS. 9 to 11. In FIGS. 9 to 11, the ozonated water and the rinsing liquid are sequentially stored in one processing tank 63. Processing shown in FIG. 9 is implemented under the control of the controller 9. First, the discharger 85 discharges the rinsing liquid used in previous batch processing from the processing tank 63 (step S201).

Subsequently, the supplier 70 supplies the ozonated water to the processing tank 63 (step S202). Even after the inner tank 63a of the processing tank 63 is filled with the ozonated water, the supplier 70 continues to supply the ozonated water to the inner tank 63a so that the ozonated water in the inner tank 63a is not deactivated, and the supplier 70 causes the ozonated water to continue to overflow from the inner tank 63a to the outer tank 63b.

Subsequently, the capturing device 88 captures an image of the ozonated water stored in the inner tank 63a (step S203). This capturing is implemented under the control of the first capturing controller 103. When the capturing device 88 captures the image of the ozonated water, the gas discharge nozzle 67 does not discharge gas to the ozonated water. This is because bubbling of the ozonated water may change the color information about the ozonated water. The capturing device 88 transmits the captured image to the controller 9.

Subsequently, the image processor 101 processes the image captured by the capturing device 88 and acquires the color information about the ozonated water (step S204). Thereafter, although not shown, the concentration calculator 102 may calculate the ozone concentration of the ozonated water based on the color information about the ozonated water acquired by the image processor 101.

Subsequently, the first determiner 104 determines whether to immerse the substrates W in the ozonated water based on the color information about the ozonated water acquired by the image processor 101 (step S205). When the color information or the ozone concentration calculated from the color information is within a set range, the first determiner 104 determines that immersion is possible. Subsequently, the driving device 65 lowers the substrate holder 64 and immerses the plurality of substrates W held by the substrate holder 64 in the ozonated water stored in the inner tank 63a (step S206).

When the color information or the ozone concentration calculated from the color information is outside the set range, the first determiner 104 determines that immersion is not possible. In this case, the discharger 85 discharges the ozonated water from the inner tank 63a, and the supplier 70 supplies new ozonated water to the inner tank 63a. Thereafter, the first determiner 104 again determines whether immersion is possible. Here, when the first determiner 104 again determines that immersion is not possible, processing of the substrates W is stopped and maintenance is performed.

Subsequently, the gas discharge nozzle 67 starts to discharge gas (step S207). The discharged gas increases the flow rate of the ozonated water and causes the ozonated water to reach resist residues before the ozonated water is deactivated. Thus, the removal efficiency of the resist residues is improved. Discharging the gas may be started (step S207) after the image of the ozonated water is captured (step S203).

Although not shown, the second capturing controller 105 may control the capturing device 88 to capture the image of the ozonated water while the plurality of substrates W is immersed in the ozonated water stored in the inner tank 63a. The second determiner 106 determines whether processing on the plurality of substrates W has been performed normally based on the color information about the ozonated water captured under the control of the second capturing controller 105.

When a time elapsing from immersion of the substrates W (step S206) reaches a set time, the supplier 70 stops the supply of the ozonated water to the inner tank 63a, and the gas discharge nozzle 67 stops the discharge of the gas (step S208).

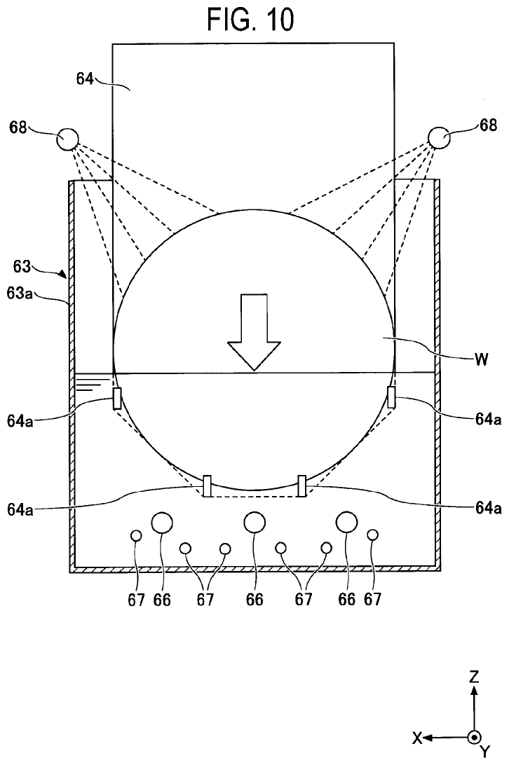

Subsequently, the discharger 85 discharges the ozonated water from the inner tank 63a (step S209). As shown in FIG. 10, the nozzle 68 may supply a shower-like or mist-like rinsing liquid to the substrates W from above to prevent the substrates W from drying while the liquid level of the ozonated water is lowered. During this time, the substrates W are accommodated inside the inner tank 63a.

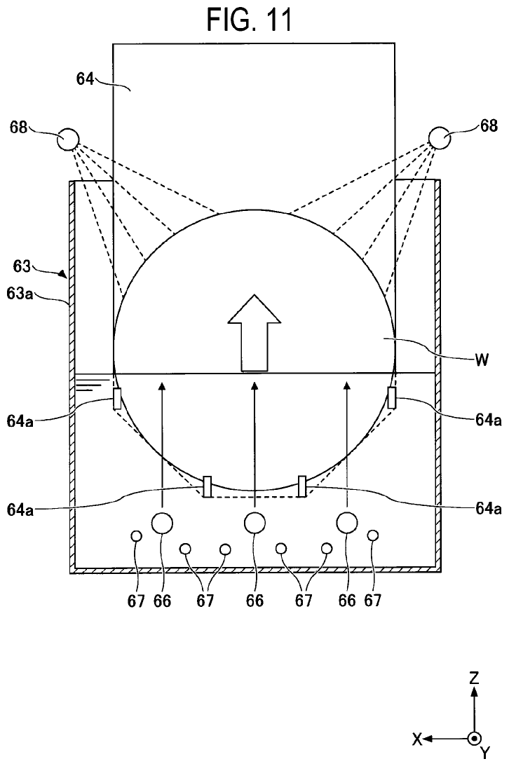

Subsequently, the supplier 70 supplies the rinsing liquid to the inner tank 63a (step S210). As shown in FIG. 11, the nozzle 68 may supply the shower-like or mist-like rinsing liquid to the substrates W from above to prevent the substrates W from drying while the liquid level of the rinsing liquid rises. During this time, the substrates W are accommodated inside the inner tank 63a.

Even after the inner tank 63a is filled with the rinsing liquid, the supplier 70 continues to supply the rinsing liquid to the inner tank 63a to cause the rinsing liquid to continue to overflow from the inner tank 63a to the outer tank 63b. The rinsing liquid removes the ozonated water remaining on the substrates W. The supply of the rinsing liquid continues for a set time.

Subsequently, the driving device 65 raises the substrate holder 64 and pulls up the plurality of substrates W held by the substrate holder 64 from the rinsing liquid stored in the inner tank 63a. Thereafter, the transferrer 52 unloads the substrates W (step S211). The substrates W may be sequentially unloaded one by one by the transferrer 52 while being immersed in the rinsing liquid.

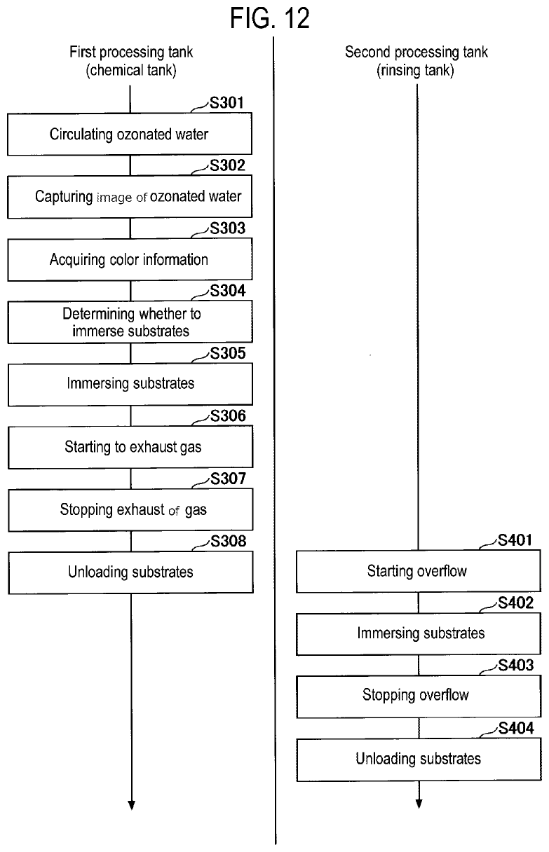

Subsequently, another example of batch processing will be described with reference to FIG. 12. In FIG. 12, two processing tanks 63 are used. One processing tank 63 is a chemical tank that stores the ozonated water. The other processing tank 63 is a rinsing tank that stores the rinsing liquid. Processing shown in FIG. 12 is performed under the control of the controller 9.

At least, the chemical tank is configured such that the circulation path 71 returns the ozonated water extracted from the outer tank 63b to the inner tank 63a, as shown in FIG. 4. The supplier 70 continues to circulate the ozonated water (step S301). In this case, the rinsing tank waits in a state in which the rinsing liquid is stored in the inner tank 63a, and stops the overflow of the rinsing liquid.

Subsequently, the controller 9 executes steps S302 to S307. Steps S302 to S307 are similar to steps S203 to S208 in FIG. 9, and thus descriptions thereof will be omitted. However, in step S307, unlike step S208 in FIG. 9, the circulation of the ozonated water continues without stopping the supply of the ozonated water.

Subsequently, the driving device 65 raises the substrate holder 64 and pulls up the plurality of substrates W held by the substrate holder 64 from the ozonated water stored in the inner tank 63a. The plurality of substrates W is unloaded, for example, by the third transfer device 62 (step S308). Thereafter, the third transfer device 62 delivers the plurality of substrates to the substrate holder 64 waiting above the rinsing tank.

While, in this embodiment, different substrate holders 64 are used for the chemical tank and for the rinsing tank, the same substrate holder 64 may be used. In the latter case, the driving device 65 may not only vertically raise and lower the substrate holder 64 but also horizontally (e.g., in the X-axis direction) move in order to transfer the plurality of substrates W between the chemical tank and the rinsing tank.

On the other hand, in the rinsing tank, the overflow of the rinsing liquid is started (step S401). The start of the overflow of the rinsing liquid (step S401) may be performed before the substrates W are immersed in the rinsing liquid (step S402).

Subsequently, the driving device 65 lowers the substrate holder 64 and collectively immerses the plurality of substrates W held by the substrate holder 64 in the rinsing liquid stored in the inner tank 63a (step S402). The rinsing liquid removes the ozonated water remaining on the substrate W. The overflow of the rinsing liquid continues for a set time.

Subsequently, the overflow of the rinsing liquid is stopped (step S403). Thereafter, the driving device 65 raises the substrate holder 64 and pulls up the plurality of substrates W held by the substrate holder 64 from the rinsing liquid stored in the inner tank 63a.

Subsequently, the transferrer 52 unloads the substrates W (step S404). The substrates W may be sequentially unloaded one by one by the transferrer 52 while being immersed in the rinsing liquid.

While the embodiments of the substrate processing system and substrate processing method according to the present disclosure have been described above, the present disclosure is not limited to the above embodiments of the present disclosure. Various changes, modifications, substitutions, additions, deletions, and combinations are possible within the scope of the claims. These naturally fall within the technical scope of the present disclosure.

The present application claims priority based on Japanese Patent Application No. 2021-111943 filed on Jul. 6, 2021, and the entirety of Japanese Patent Application No. 2021-111943 is incorporated into this application.

### EXPLANATION OF REFERENCE NUMERALS

1: substrate processing system, 3: single-substrate processor, 52; transferrer, 6: batch processor, 63: processing tank, W: substrate

1-11. (canceled)

12. A substrate processing system, comprising a batch processor configured to collectively process a plurality of substrates by immersing the plurality of substrates in ozonated water stored in a processing tank;
a single-substrate processor configured to process the plurality of substrates one by one with a chemical liquid; and
a transferrer configured to transfer the plurality of substrates in a wet state from the batch processor to the single-substrate processor.

13. The substrate processing system of claim 12, further comprising:
a capturing device configured to capture an image of the ozonated water stored in the processing tank;
an image processor configured to process the image captured by the capturing device and acquire color information about the ozonated water; and
a concentration calculator configured to calculate an ozone concentration of the ozonated water based on the color information about the ozonated water acquired by the image processor.

14. The substrate processing system of claim 12, further comprising:
a capturing device configured to capture an image of the ozonated water stored in the processing tank;
an image processor configured to process the image captured by the capturing device and acquire color information about the ozonated water; and
a first determiner configured to determine whether to immerse the plurality of substrates in the ozonated water based on the color information about the ozonated water acquired by the image processor.

15. The substrate processing system of claim 13, further comprising: a first capturing controller configured to control the capturing device to capture the image of the ozonated water before the plurality of substrates is immersed in the ozonated water after the ozonated water is stored in the processing tank.

16. The substrate processing system of claim 13, further comprising:
a second capturing controller configured to control the capturing device to capture the image of the ozonated water while the plurality of substrates is immersed in the ozonated water stored in the processing tank; and
a second determiner configured to determine whether processing on the plurality of substrates has been performed normally based on the color information about the ozonated water captured under the control of the second capturing controller.

17. The substrate processing system of claim 12, wherein each of the plurality of substrates has a resist residue adhering thereto,
wherein the ozonated water oxidizes the resist residue, and
wherein the chemical liquid dissolves and removes the resist residue oxidized by the ozonated water.

18. The substrate processing system of claim 17, wherein the batch processor includes a circulation path through which the ozonated water circulates, an ozone gas supplier configured to supply an ozone gas to the circulation path, a pressurizing device configured to pressurize the ozonated water in the circulation path, and a cooling device configured to cool the ozonated water in the circulation path.

19. The substrate processing system of claim 14, further comprising: a first capturing controller configured to control the capturing device to capture the image of the ozonated water before the plurality of substrates is immersed in the ozonated water after the ozonated water is stored in the processing tank.

20. The substrate processing system of claim 14, further comprising:
a second capturing controller configured to control the capturing device to capture the image of the ozonated water while the plurality of substrates is immersed in the ozonated water stored in the processing tank; and
a second determiner configured to determine whether processing on the plurality of substrates has been performed normally based on the color information about the ozonated water captured under the control of the second capturing controller.

21. The substrate processing system of claim 12, wherein the batch processor includes a circulation path through which the ozonated water circulates, an ozone gas supplier configured to supply an ozone gas to the circulation path, a pressurizing device configured to pressurize the ozonated water in the circulation path, and a cooling device configured to cool the ozonated water in the circulation path.

22. A substrate processing method, comprising:
collectively processing a plurality of substrates by immersing the plurality of substrates in ozonated water stored in a processing tank; and
transferring the plurality of substrates in a wet state from the batch processor to a single-substrate processor,
wherein the single-substrate processor processes the plurality of substrates one by one with a chemical liquid.

23. The substrate processing method of claim 22, further comprising:
capturing, by a capturing device, an image of the ozonated water stored in the processing tank before the plurality of substrates is immersed in the ozonated water stored in the processing tank;
processing, by an image processor, the image captured by the capturing device and acquiring color information about the ozonated water; and
immersing the plurality of substrates in the ozonated water stored in the processing tank when the color information about the ozonated water acquired by the image processor satisfies a preset condition.

24. The substrate processing method of claim 22, further comprising:
capturing, by a capturing device, an image of the ozonated water stored in the processing tank while the plurality of substrates is immersed in the ozonated water stored in the processing tank;
processing, by an image processor, the image captured by the capturing device and acquiring color information about the ozonated water; and
determining whether processing on the plurality of substrates has been performed normally, based on whether the color information about the ozonated water acquired by the image processor satisfies a preset condition.

25. The substrate processing method of claim 22, wherein each of the plurality of substrates has a resist residue adhering thereto,
wherein the ozonated water oxidizes the resist residue, and
wherein the chemical liquid dissolves and removes the resist residue oxidized by the ozonated water.
